(19) United States
(12) Patent Application Publication
(10) Pub. No.: US 2013/0206843 A1
(43) Pub. Date: Aug. 15, 2013

(54) INTEGRATED CIRCUIT PACKAGE

(71) Applicant: Robert Fabian McCarthy, Dallas, TX (US)

(72) Inventor: Robert Fabian McCarthy, Dallas, TX (US)

(73) Assignee: TEXAS INSTRUMENTS INCORPORATED, Dallas, TX (US)

(21) Appl. No.: 13/396,265

(22) Filed: Feb. 14, 2012

(51) Int. Cl. G06K 19/07; G11C 5/02; H03K 19/00; H01L 21/58

(52) U.S. Cl. 235/492; 438/106; 365/51; 326/8; 257/E21.505

(57) ABSTRACT

An integrated circuit package that includes a first die with a memory positioned physically at a predetermined memory location in the first die; a second die positioned in covering relationship with at least the predetermined memory location in the first die; penetration detection circuitry, positioned at least partially in said second die, that generates a penetration detection signal in response to physical penetration of the second die; and memory circuitry operatively associated with the memory in the first die and the penetration detection circuitry, which is adapted to perform an operation on the memory, such as data erasure, in response to the penetration detection signal.

### BACKGROUND

The term “payment card” refers to a card that may be presented by a cardholder to make a payment. There are different types of payment cards used for various transactions. Credit cards, debit cards, charge cards, stored-value cards, fleet cards, and gift cards are all payment cards. Virtually all payment cards include an integrated circuit package that has a memory provided on a semiconductor die. In many types of payment cards, confidential information such as security codes, financial information, or other data of a proprietary nature is stored in the memory.

### BRIEF DESCRIPTION OF THE DRAWINGS

FIG. 1 is a truncated cross sectional view of an integrated circuit package.

FIG. 2 is a top plan view of a substrate and first die of the integrated circuit package of FIG. 1.

FIG. 3 is a top plan view of a second die of the integrated circuit package of FIG. 1.

FIG. 4 is a cross sectional view of a portion of a payment card incorporating the integrated circuit package of FIG. 1.

FIG. 5 is a perspective view of the payment card of FIG. 4.

FIG. 6 is a circuit diagram of the penetration detection circuitry of the integrated circuit package of FIG. 1.

FIG. 7 is a block diagram illustrating the operation of circuitry of the integrated circuit package of FIG. 1.

FIG. 8 is a flow chart of a method of preventing unauthorized access to data in a memory of a first semiconductor die that is covered by a second semiconductor die.

FIG. 9 is a flow chart illustrating a method of making a tamper resistant integrated circuit package.

### DETAILED DESCRIPTION

The use of payment cards has become ubiquitous in modern society. Not surprisingly, payment card fraud has become a huge problem, costing card owners and the institutions that issue such cards millions of dollars daily. One manner in which such fraud is practiced is through the perpetrator's obtaining unauthorized access to proprietary data in the card memory. One techniques used to obtain such access involves insertion of a physical probe, a needle like object, through the surface of the card and into the card memory or a memory access point. Sophisticated electronics are then used to read or copy the information in the memory. Applicant has developed an integrated circuit package that may be used in a payment card to prevent such unauthorized access to stored information.

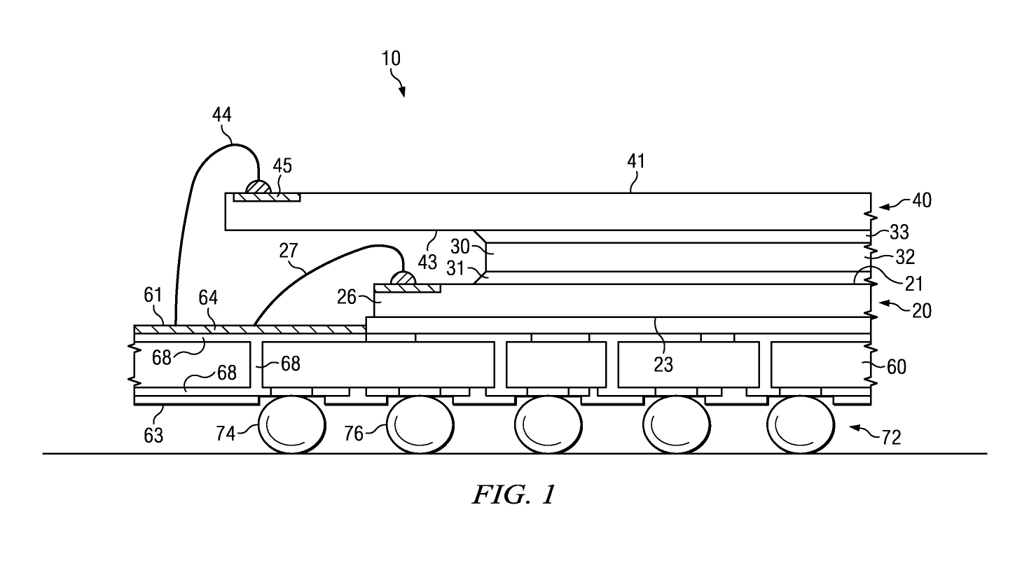

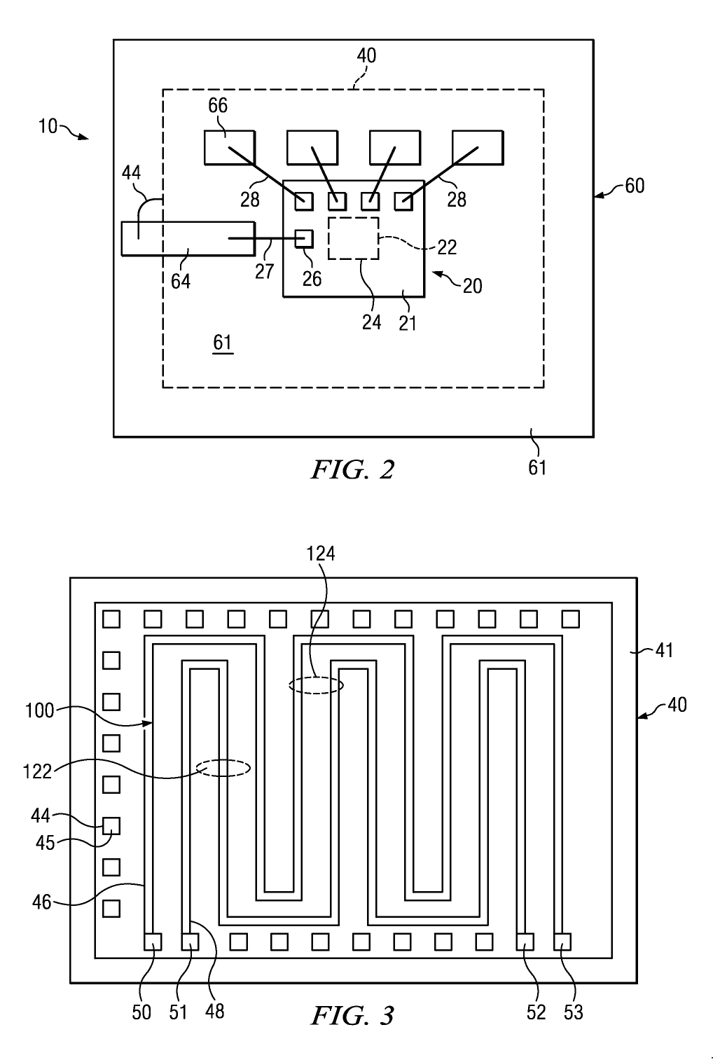

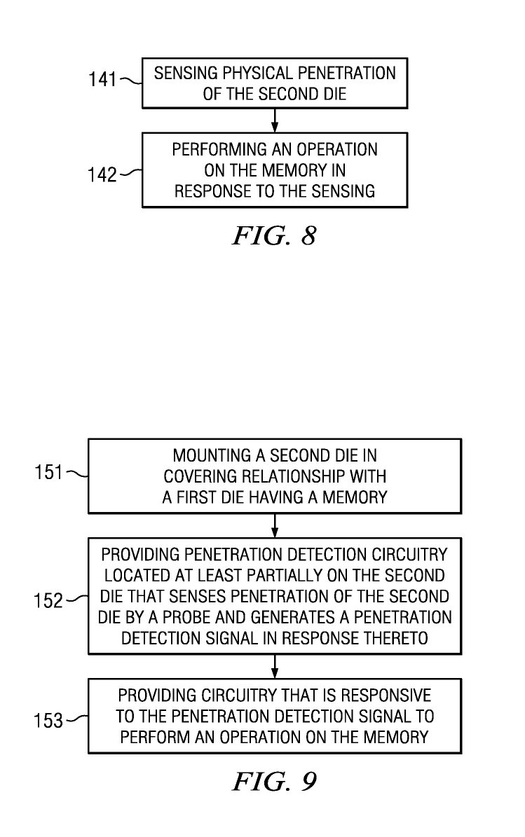

FIGS. 1-7, in general, disclose an integrated circuit package 10 including a first semiconductor die 20 (sometimes referred to herein as “first die 20”) and a second semiconductor die 40 (sometimes referred to herein as “second die 40”). The first die 20 has a memory 22, FIG. 2, positioned physically at a predetermined memory location 24 in the first die 20. The second die 40 is positioned in covering relationship with at least the predetermined memory location 24 in the first die 20. The second die 40 may be electrically connected to the first die 20. Penetration detection circuitry 100, etc., FIGS. 3 and 6, is positioned at least partially in the second die 40. The penetration detection circuitry generates a penetration detection signal 108 in response to physical penetration of the second die 40. Memory erasure circuitry 110 is operatively associated with the memory 22 in the first die 20 and the penetration detection circuitry 100, etc. and is adapted to erase or otherwise prevent accurate copying of the memory 22 in response to the penetration detection signal 108. A method of making such an integrated circuit package, FIG. 8, and a method of using an integrated circuit package 10 to protect data, FIG. 9, are also described. Having thus described an integrated circuit package and methods of making and using an integrated circuit package generally, various details thereof will now be described in further detail.

FIG. 1 is a partial cross sectional view of an integrated circuit package 10. FIG. 2 is a top plan view of the integrated circuit package 10 with an upper portion thereof removed. The integrated circuit package 10 includes a first semiconductor die 20 having a generally flat top surface 21 and an opposite, generally flat bottom surface 23. A plurality of contact pads 26 are formed on the top surface 21. The contact pads may be electrically connected to other components by bond wires 27, 28. The formation of contact pads on a die and the connection of contact pads to other devices with bond wires is well known in the art and will thus not be further described herein. As best illustrated in FIG. 1, the first semiconductor die 20 is attached by a connecting structure 30 to a second semiconductor die 40 (“die 40”). The connecting structure 30 may be conventional die connecting structure comprising a first layer 32 of die attach paste, a second layer 33 that may be a silicon spacer or the like, and a third layer 34 of die attach paste. Such die connecting structure is well known in the art. The first die 20 comprises a memory 22, which is physically located in the first die 20 at a predetermined memory location 24, FIG. 2. In some embodiments, the memory 22 stores proprietary information such as financial data and security codes.

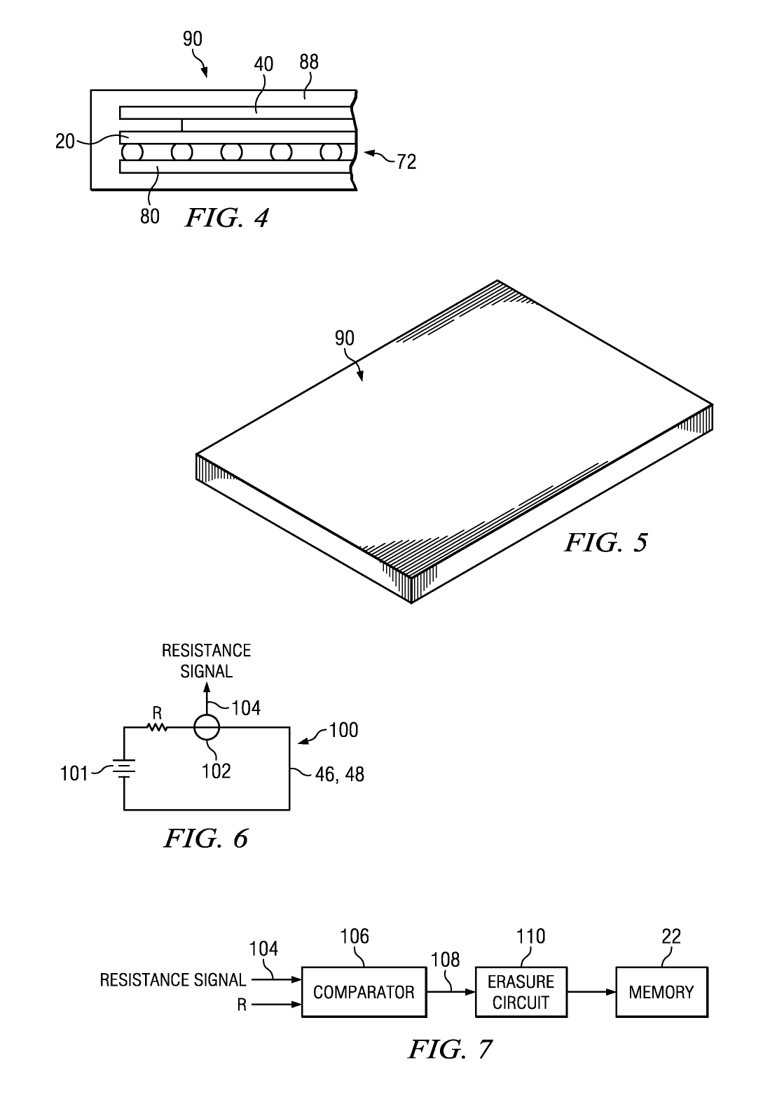

The second die 40 is positioned in overlying relationship with the first die 20 and covers at least memory location 24 and any contact pads 26 or electrical connectors such as bond wires 27, 28 which might allow access to the memory 22. The footprint of the second die 40 with respect to the first die 20, in one embodiment of the integrated circuit package 10, is illustrated in FIG. 2. Such a stacked die arrangement wherein the top die is larger than the bottom die is known as a “reverse pyramid stack.” The second die 40 has a generally flat top surface 41 and an opposite, generally flat bottom surface 43, FIG. 1. As illustrated by FIG. 3, the top surface 41, in one embodiment, comprises a first trace 46 and a second trace 48 positioned in generally parallel relationship in a serpentine pattern which may substantially cover the entire top surface 41 of the second die 40. The traces 46, 48 may be connected at opposite ends thereof to contact pads 50, 51, 52, 53. The contact pads 50 through 53 may connect the traces 46, 48 to other circuitry within the second die 40 or may connect the traces to other circuitry in the first die 20 or an associated printed circuit board 80, FIG. 4. Operation of this other circuitry will be described in further detail below. The purpose of the first and second traces 46, 48 is to provide a “screen” which will sense any attempted penetration of the second die 40 as will also be discusses in further detail below.

The first die 20 may be mounted on a substrate 60 having a generally flat top surface 61 and a generally flat bottom surface 63. As illustrated by FIGS. 1 and 2, the substrate 60 may be an electrical connection substrate, which in the illustrated embodiment comprises a conventional ball grid array substrate. The substrate 60 may comprise a plurality of contact pads 64, 66, etc., FIG. 2, provided on top surface 61. The contact pads 64, 66, etc., may be connected by internal electrical routing 68, FIG. 1, to a ball grid array 72 comprising a plurality of solder balls 74, 76, etc. The construction of ball grid array substrates is well known in the art and will thus not be further described herein. The solder balls 74, 76 may be connected by reflow soldering to contacts on a PC board 80, FIG. 4. Various other types of electrical connection substrates, for example those having pin type connectors, may also be used.

The first and second dies 20, 40, the connecting substrate 60 and the PC board 80 may be suitably encased in mold compound 88, FIGS. 4 and 5, which is typically plastic (epoxy), to provide a tamper resistant payment card 90. The payment card 90 may be provided with appropriate surface contacts (not shown) or other electrical communication structure which enable it to be placed in communication with other devices, depending upon the type of payment card. For example, payment card 90 may be an ATM card, credit card, gift card, or other type of payment card, each of which is associated with a particular type of reader or other interaction device. The integrated circuit package 10 including the first die 20, second die 40 and substrate 60 may be initially encased in transfer mold, and then mounted on a PC board 80. This assembly may be further encased in other materials depending upon the type and use of the particular payment card 90. In another embodiment the first die 20, second die 40, substrate 60 and PC board 80 may are all first connected together and are then encased in mold compound or the like in a single encapsulation operation.

As shown schematically in FIG. 6, penetration detection circuitry 100 may include a voltage source 101 connected to traces 46, 48. These traces have a normal combined resistance “R.” The penetration detection circuitry 100 may further include a resistance sensor 102 that generates a signal 104 indicative of the resistance in the circuit 100. As will be understood by those skilled in the art, the resistance detector 102 may comprise a volt meter or amp meter. Referring to FIG. 3, the spacing of the traces 46, 48 in the serpentine network is sufficiently close such that any typical conductive probe which penetrates the top surface 41 of the first die 40 will either break or short the circuit. A circuit break (open circuit) caused by a probe is illustrated at 122 and a circuit short caused by a probe is illustrated at 124. A break will cause a substantial increase in the resistance of the circuit and a short in the circuit will cause a substantial decrease in the resistance of the circuit. In one embodiment the space between traces 46, 48 may be less than about 10 microns, to ensure that penetration by any probe having a minimum cross sectional dimension greater than 10 microns will be detected. Any desired spacing between traces 46, 48 may be provided. Also, rather than two traces 46, 48 only one trace or more than two traces may be used with suitable modifications to circuit 100.

The resistance signal 104 may be used to detect a penetration of the first die 40 by a probe by comparing the present resistance of the circuit 100 to the known resistance R of the circuit when it is in an undamaged state. To implement such a comparison, the resistance signal 104 may be transmitted to a comparator 106, FIG. 7, which compares the resistance value of signal 104 to the known resistance R of the circuit 100 in an undamaged state. If the resistance indicated by signal 104 is more than the known prior resistance R by more than a predetermined amount, then a penetration detection signal 108 is generated by the comparator circuit 106. Similarly, if the present resistance indicated by circuit 104 is less than the known resistance R by a predetermined amount, a penetration detection signal 108 is also generated. The penetration detection signal 108 triggers erasure circuitry 110 to erase the memory 22. An integrated circuit memory may be erased by any of the various techniques known in the art or other techniques now known or later developed. Rather than erasing the data in memory 22, some other operation may be performed on the memory 22 to prevent data therein from being accurately read. The circuitry for performing the operations indicated in the block diagram of FIG. 7 may be provided either in the first die 20 or in the second die 40 or partially in both dies 20, 40, or some combination of dies 20, 40 and PC board 80, FIG. 4. For example, in an embodiment in which erasure circuitry 110 is provided in the first die 20 and the circuitry 100, 106 is provided in second die 40, the signal 108 may be transmitted through a bond wire 44 connected to a contact pad 45 on the second die 40, FIG. 1, which is in turn connected to a contact pad 64 on substrate 60. Contact pad 64 on substrate 60 may in turn have a bond wire 27 connecting it to a contact pad 26 on the first die 20.

FIG. 8 illustrates a method of preventing unauthorized access to data in a memory 22 of a first semiconductor die 20 that is covered by a second semiconductor die 40. The method includes, as indicated at 141, sensing physical penetration of the second die 40. The method also includes, as shown at 142, performing an operation on the memory 22 in response to the sensing of physical penetration of the second die 40.

FIG. 9 illustrates a method of making a tamper resistant integrated circuit package 10. The method includes, as shown at 151, mounting a second die 40 in covering relationship with a first die 20 having a memory 22. The method further includes, as shown at 152, providing penetration detection circuitry 100, 106, 110, located at least partially on the second die 40, which senses penetration of the second die 40 by a probe and generates a penetration detection signal 108 in response thereto. The method also includes, as shown at 153, providing circuitry that is responsive to the penetration detection signal 108 to perform an operation on the memory 22 that prevents unauthorized access of data in the memory.

While certain illustrative embodiments of an integrated circuit package and associated methodology have been described in detail herein, it will be obvious to those with ordinary skill in the art after reading this disclosure that the disclosed integrated circuit package and methodology may be variously otherwise embodied and employed. The appended claims are intended to be construed to include such variations except insofar as limited by the prior art.

What is claimed is:

1. An integrated circuit package comprising:
a first die having a memory positioned physically at a predetermined memory location in said first die;
a second die positioned in covering relationship with at least said predetermined memory location in said first die and electrically connected to said first die;
penetration detection circuitry, positioned at least partially in said second die, that generates a penetration detection signal in response to physical penetration of said second die; and
memory circuitry operatively associated with said memory in said first die and said penetration detection circuitry and adapted to perform an operation on said memory in response to said penetration detection signal.

2. The integrated circuit package of claim 1 comprising an interface substrate adapted to electrically connect at least said first die to a printed circuit board; wherein at least said first die is mounted on and electrically connected to said interface substrate.

3. The integrated circuit package of claim 1 wherein said penetration detection circuitry comprises at least one electrical trace arranged in said second die in a screening pattern above at least said predetermined memory location on said first die.

4. The integrated circuit package of claim 3 wherein said penetration detection circuitry is arranged in a serpentine pattern.

5. The integrated circuit package of claim 3 wherein said penetration detection circuitry detects changes in resistance in said at least one electrical trace.

6. The integrated circuit package of claim 3 wherein said at least one trace is electrically connected to said first die by wire bonding.

7. The integrated circuit package of claim 1 wherein said memory circuitry comprises memory erasure circuitry that erases said memory in response to said detection signal.

8. The integrated circuit package of claim 2 wherein said first die comprises a plurality of electrical connection(s) connecting said first die to said interface substrate and wherein said penetration detection circuitry comprises a plurality of electrical traces arranged in said second die in a screening pattern above at least said predetermined memory location on said first die and all of said plurality of electrical connection on said first die.

9. The integrated circuit package of claim 1, wherein said first and second dies are arranged in a reverse pyramid stack.

10. The integrated circuit package of claim 1 wherein said first and second dies are encapsulated in protective material.

11. The integrated circuit package of claim 2 wherein said interface substrate comprises a ball grid array.

12. The integrated circuit package of claim 2 further comprising a printed circuit board, wherein said interface substrate is physically and electrically connected to said printed circuit board

13. A method of preventing unauthorized access to data in a memory of a first semiconductor die that is covered by a second semiconductor die, comprising:
sensing physical penetration of the second die; and
performing an operation on the memory in response to said sensing.

14. The method of claim 13 wherein said performing an operation on the memory comprises erasing the data in the memory.

15. The method of claim 13 wherein said sensing comprises detecting a change in the resistance of a conductor pattern provided in said second die.

16. The method of claim 13 further comprising mounting the first die in covering relationship with a substrate.

17. The method of claim 16 wherein said mounting the first die in covering relationship with a substrate comprises mounting the first die in covering relationship with an electrical connection substrate.

18. The method of claim 17 wherein said mounting the first die in covering relationship with an electrical connection substrate comprises mounting the first die in covering relationship with an electrical connection substrate comprising a ball grid array.

19. A method of making a tamper resistant integrated circuit package comprising:
mounting a second die in covering relationship with a first die having a memory;
providing penetration detection circuitry located at least partially on said second die that senses penetration of the second die by a probe and generates a penetration detection signal in response thereto; and
providing circuitry that that performs an operation on the memory in response to said penetration detection signal.

20. The method of claim 19 wherein said providing a penetration detection circuit located at least partially on said second die that senses penetration of the second die by a probe and generates a penetration signal in response thereto comprises:
providing a routing of closely spaced conductors on the second die which are spaced closely enough such that they are subject to being ruptured and/or short circuited by a probe having a diameter of at least 10 microns; and
connecting resistance change measurement circuitry to the routing of closely spaced conductors which provides a resistance change signal indicative of a change in resistance in the routing of closely spaced conductors when a change in resistance thereof is greater than a predetermined magnitude; and
providing the resistance change signal to the circuitry that that performs an operation on the memory.

21. A payment card comprising:
a first die having a memory positioned physically at a predetermined memory location in said first die that is readable by an authorized payment card reading device; and
a memory protection assembly that erases said memory in response to an unauthorized attempt to access said memory.

22. The payment card of claim 21 wherein said memory protection assembly comprises:
a second die positioned in covering relationship with at least said predetermined memory location in said first die and electrically connected to said first die;
penetration detection circuitry, positioned at least partially in said second die, that generates a penetration detection signal in response to physical penetration of said second die; and
memory circuitry operatively associated with said memory in said first die and said penetration detection circuitry and adapted to erase said memory in response to said penetration detection signal.

23. The payment card of claim 22 comprising an electrical connection substrate, wherein said first die is mounted on said electrical connection substrate.

24. The payment card of claim 22 wherein said first die is electrically connected to said electrical connection substrate.

25. The payment card of claim 23 comprising a printed circuit board, wherein said electrical connection substrate is electrically and physically connected to said printed circuit board.

26. The payment card of claim 24 comprising encapsulant wherein said first and second dies, said electrical connection substrate and said printed circuit board are encased in said encapsulant.

27. The payment card of claim 25 wherein said electrical connection substrate is connected to said printed circuit board by a ball grid array.

28. The payment card of claim 24 wherein said second die is electrically connected to said electrical connection substrate.
